(19) United States
(12) Patent Application Publication
(10) Pub. No.: US 2025/0264810 A1
(43) Pub. Date: Aug. 21, 2025

(54) METHOD OF CONFIGURING EXTREME ULTRAVIOLET (EUV) SOURCE, AND EUV EXPOSURE METHOD USING THE EUV SOURCE

(71) Applicant: SAMSUNG ELECTRONICS CO., LTD., Suwon-si (KR)

(72) Inventors: Hyung Jong BAE, Suwon-si (KR); Sudeok KIM, Suwon-si (KR); Seongbo SHIM, Suwon-si (KR); Chan HWANG, Suwon-si (KR)

(73) Assignee: SAMSUNG ELECTRONICS CO., LTD., Suwon-si (KR)

(21) Appl. No.: 19/030,117

(22) Filed: Jan. 17, 2025

(30) Foreign Application Priority Data
Feb. 15, 2024 (KR) 10-2024-0022003

(51) Int. Cl. G03F 7/00

(52) U.S. Cl. CPC G03F 7/70516; G03F 7/70033; G03F 7/70075; G03F 7/70141; G03F 7/702

(57) ABSTRACT

Provided are a method of configuring an extreme ultraviolet (EUV) source capable of improving optical performance before an exposure process and an EUV exposure method using the EUV source. The method of configuring an EUV source includes generating an object spectrum map for a layout of a mask pattern, generating a pupil map corresponding to the object spectrum map, and configuring an EUV illumination mode by selecting mirrors in at least a portion of a first region of the pupil map in which a certain condition is satisfied, and applying perturbation of a pole balance to the plurality of mirrors.

### CROSS-REFERENCE TO RELATED APPLICATION

This application is based on and claims priority under 35 USC § 119 to Korean Patent Application No. 10-2024-0022003, filed on Feb. 15, 2024, in the Korean Intellectual Property Office, the disclosure of which is incorporated by reference herein in its entirety.

### BACKGROUND

The disclosure relates to an extreme ultraviolet (EUV) light source, and more particularly, to a method of configuring an EUV source related to optimization of an EUV illumination mode and an EUV exposure method using the EUV source.

Recently, as semiconductor circuit line widths have become increasingly finer, there is a need for light sources having shorter wavelengths. For example, EUV is being used as an exposure light source, and a number of layers of a semiconductor device that use EUV as an exposure light source has increased. Due to the absorption characteristics of EUV, a reflective EUV mask has been generally used during an EUV exposure process. In addition, illumination optics for transmitting EUV to the EUV mask and projection optics for projecting EUV reflected from the EUV mask to an exposure target may include a plurality of mirrors.

### SUMMARY

One or more aspects of the disclosure provide a method of configuring an extreme ultraviolet (EUV) light source that improves optical performance before an exposure process, and an EUV exposure method using the EUV source.

According to an aspect of the disclosure, there is provided a method of configuring an extreme ultraviolet (EUV) source, the method including: generating an object spectrum map for a layout of a mask pattern; generating a pupil map corresponding to the object spectrum map; and configuring an EUV illumination mode by: selecting a plurality of mirrors in a first region of the pupil map based on a first condition being satisfied, and applying perturbation of a pole balance to the plurality of mirrors.

According to another aspect of the disclosure, there is provided a method of configuring an extreme ultraviolet (EUV) source, the method including: generating an object spectrum map for a layout of a mask pattern; generating a pupil map corresponding to the object spectrum map; and based on one of a maximum overlap region in which a largest number of beams overlap in the pupil map or a next maximum overlap region in which a next largest number of beams overlap being greater than or equal to an area of illumination efficiency 1, configuring an EUV illumination mode by: selecting a plurality of mirrors in at least a portion of a first region including the maximum overlap region or the next the maximum overlap region, and applying perturbation of a pole balance to introduce asymmetry of the pupil map.

According to another aspect of the disclosure, there is provided an extreme ultraviolet (EUV) exposure method including: obtaining a target pattern; configuring an EUV mask and an EUV source corresponding to the target pattern; and performing EUV exposure on a wafer using the EUV source and the EUV mask, wherein the configuring of the EUV source includes: generating an object spectrum map for a layout of the mask pattern on the EUV mask; generating a pupil map corresponding to the object spectrum map; and based on one of a maximum overlap region in which a largest number of beams overlap in the pupil map or a next maximum overlap region in which a next largest number of beams overlap being greater than or equal to an area of illumination efficiency 1, configuring an EUV illumination mode by: selecting a plurality of mirrors in at least a portion of a first region including the maximum overlap region or the next the maximum overlap region, and applying perturbation of a pole balance to introduce asymmetry of the pupil map.

### BRIEF DESCRIPTION OF DRAWINGS

Embodiments will be more clearly understood from the following detailed description taken in conjunction with the accompanying drawings in which:

FIG. 1 is a flowchart schematically illustrating a method of configuring an extreme ultraviolet (EUV) light source according to an embodiment;

FIGS. 2A and 2B are conceptual diagrams of object spectrum maps in the method of configuring an EUV source of FIG. 1;

FIG. 3 is a conceptual diagram of a pupil map in relation to the method of configuring the EUV source of FIG. 1;

FIGS. 4A to 4E are conceptual diagrams of various EUV illumination modes configured by applying perturbation of a pole balance in the method of configuring an EUV source of FIG. 1 and layouts of mask patterns corresponding thereto;

FIG. 5A is a conceptual diagram of a crosspole illumination mode and a scanning electron microscope (SEM) image of a target pattern according to a comparative example and FIG. 5B is a conceptual diagram of a Y-dipole illumination mode and a scanning electron microscope (SEM) image of a target pattern based on a method of configuring an EUV source according to an embodiments;

FIGS. 6A to 6C are conceptual diagrams illustrating the concepts of mask pattern layout, aerial image, and normalized image log slope (NILS) in relation to the method of configuring an EUV source of FIG. 1; and

FIG. 7 is a flowchart schematically illustrating an EUV exposure method using an EUV source according to an embodiment.

### DETAILED DESCRIPTION

Hereinafter, embodiments are described in detail with reference to the attached drawings. The same reference numerals are used for the same components in the drawings, and redundant descriptions thereof are omitted.

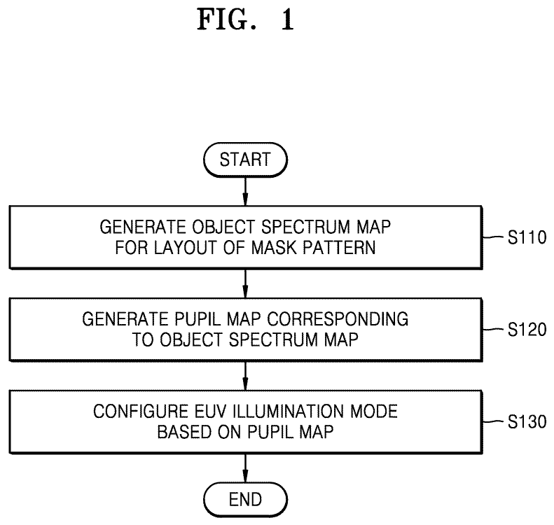

FIG. 1 is a flowchart schematically illustrating a method of configuring an extreme ultraviolet (EUV) source according to an embodiment.

Before describing a method of configuring an EUV source according to an embodiment with reference to FIGS. 1, an EUV facility is briefly described. the EUV facility may include an EUV light source, a first optical system, a second optical system, an EUV mask, and a wafer. The EUV light source may generate and output EUV light with high energy density. For example, the EUV light may be within a wavelength range of about 5 nm to about 50 nm. For example, the EUV light source may generate and output EUV light with high energy density having a wavelength of 13.5 nm or about 13.5 nm. The EUV light source may be a plasma-based light source or a synchrotron radiation light source. Here, the plasma-based light source refers to a light source that generates plasma and uses light emitted by the plasma. For example, the plasma-based light source may include, but is not limited to, a laser-produced plasma (LPP) light source, or discharge-produced plasma (DPP) light source.

The first optical system may include a plurality of mirrors Mr. The first optical system may be referred to as an EUV illumination optical system or an EUV illumination mode. According to an embodiment, in the method of configuring the EUV source, the EUV source may include the EUV light source, the first optical system, and the second optical system. However, the disclosure is not limited thererto, and as such, in some embodiments, the EUV source may be same as the EUV illumination mode.

The first optical system may transmit the EUV light from the EUV light source to the EUV mask. For example, the EUV light from the EUV light source may be incident on the EUV mask on a mask stage through reflection by the mirrors in the first optical system. According to an embodiment, the first optical system may form the EUV light to have a curved slit shape and make the EUV light incident on the EUV mask. Here, the curved slit shape of EUV light may refer to a parabolic two-dimensional curve on the x-y plane.

The EUV mask may be a reflective mask having a reflective region, a non-reflective and/or intermediate reflective region. The EUV mask may include a substrate, a reflective multilayer film on the substrate, and an absorption layer formed on the reflective multilayer film. For example, the substrate may include a low thermal expansion coefficient material (LTEM), such as quartz. The reflective multilayer film may reflect the EUV light. For example, the reflective multilayer film may have a structure in which molybdenum (Mo) layers and silicon (Si) layers) are alternately stacked in a plurality of layers. According to an embodiment, the absorption layer may include, for example, TaN, TaNO, TaBO, Ni, Au, Ag, C, Te, Pt, Pd, Cr, etc. However, the material of the reflective multilayer film and the material of the absorption layer are not limited to the aforementioned materials. Here, the absorption layer portion may correspond to the non-reflective and/or intermediate reflective region mentioned above.

The EUV mask reflects the EUV light from the first optical system to be incident on the second optical system. For example, the EUV mask structures the EUV light according to a pattern shape formed by the reflective multilayer film and the absorption layer on the substrate, such that the EUV light reflected on to the optical system is the structure EUV light. The EUV light may be structured to include at least one secondary diffraction light based on the pattern on the EUV mask. The structured EUV light may be incident on the second optical system while retaining information in the form of a pattern on the EUV mask and may be projected on an EUV exposure target through the second optical system. The EUV exposure target may be the wafer, The second optical system may be referred to as EUV projection optics. The second optical system may include a plurality of mirrors.

The EUV mask may be placed on the mask stage. The EUV mask may move in an x direction, y direction, or z direction by moving the mask stage and may also rotate about an x-axis, y-axis, or z-axis. For example, the movement in the x direction or the y direction may be a horizontal movement, and the z direction may be a vertical movement. The wafer subject to EUV exposure may be located on a wafer stage. The wafer may move in the x-direction, y-direction, or z-direction by moving the wafer stage. Moreover, the wafer W may also rotate about the x-axis, y-axis, or z-axis by rotating the wafer stage.

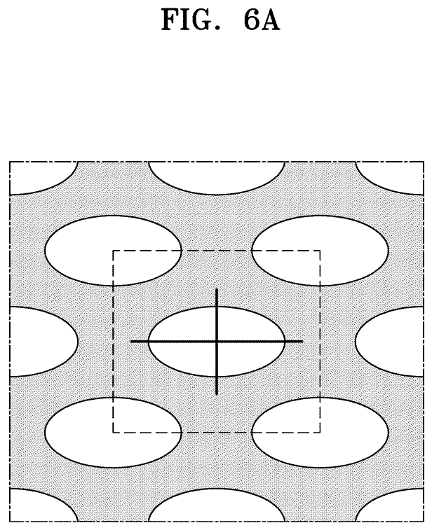

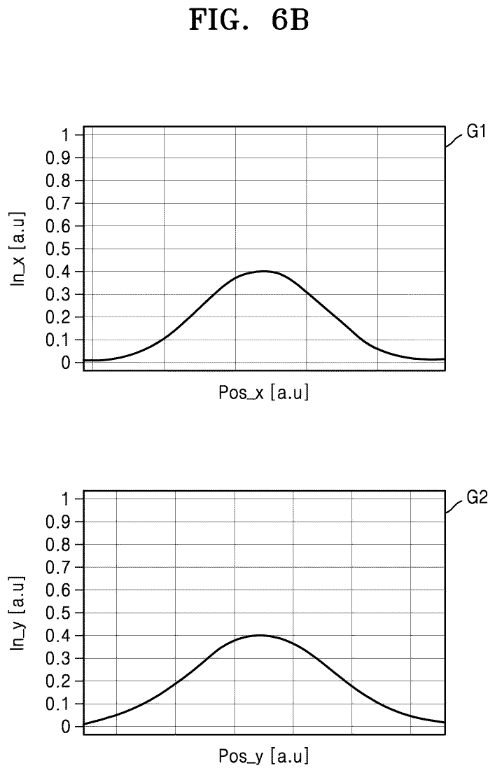

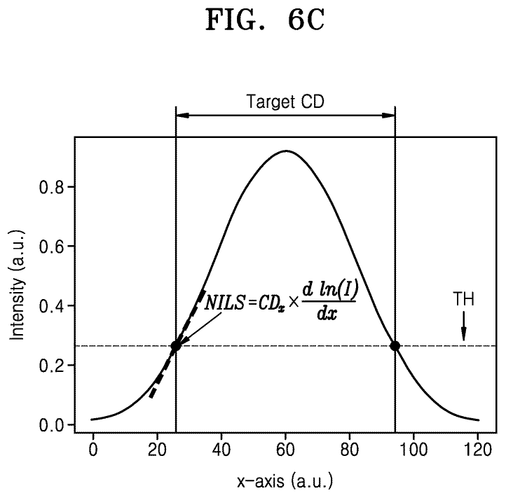

According to an embodiment, in operation S110, a method of configuring an EUV source may include generating an object spectrum map for a layout of a mask pattern. According to an embodiment, the method may include obtaining information on the mask pattern. For example, the method may include obtaining the information on the mask pattern before generating the object spectrum map for the layout of the mask pattern. In an example case in which the mask pattern is a repeated pattern, the information on the mask pattern may include, but is not limited to, a pitch of the repeated pattern, a target critical dimension (CD), characteristics, and gauge of the mask pattern. Here, the characteristics may include optical performances, such as an aspect ratio (or long/short ratio) of a CD, dose, local CD uniformity (LCDU), normalized image log slope (NILS), in point uniformity (IPU), mask error enhancement factor (MEEF), and depth of focus (DoF). However, the characteristics are not limited to the above optical performances. For reference, the gauge is a 1D line extracted in relation to the optical performance of an optimization target and may usually refer to cutlines of the x-axis and y-axis of the mask pattern. The NILS refers to an optical performance showing the characteristics that, as the NILS value increases, the CD changes to be smaller over a process change. The cut lines of the x-axis and y-axis and NILS are described in more detail below with reference to FIGS. 6A to 6C. In some embodiments, the characteristics may be referred to as constraints or conditions.

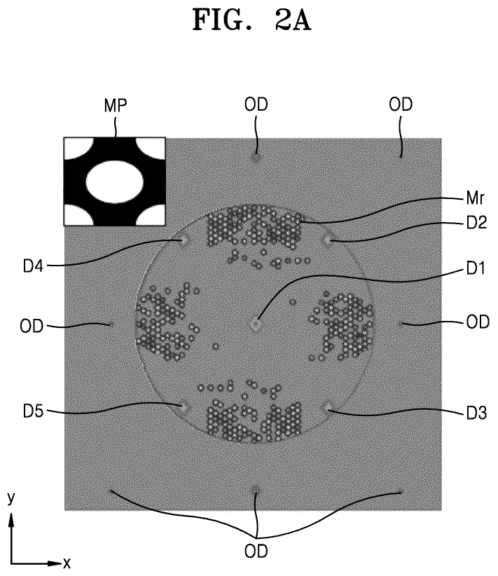

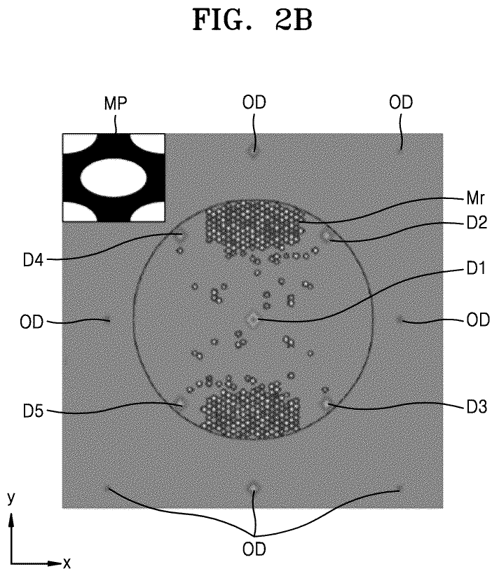

The object spectrum map may be generated based on the layout of the mask pattern. The object spectrum map may be generated in an automated manner to some extent. For example, in a case in which the layout of the mask pattern is received, the shape of the layout may be parameterized, and the object spectrum map may be automatically generated through a map generation tool based on the parameter. The object spectrum map is described in more detail below with reference to FIGS. 2A and 2B.

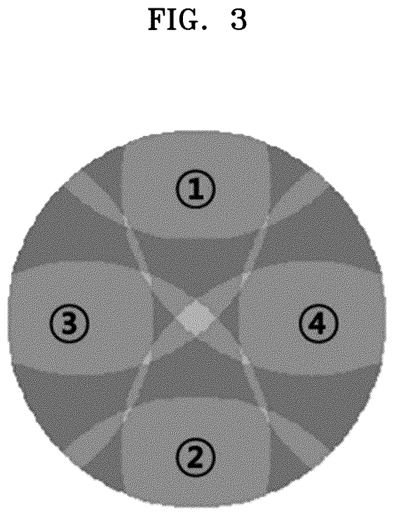

In operation S120, the method may include generating pupil map corresponding to the object spectrum map. For example, after the object spectrum map is generated, a pupil map corresponding to the object spectrum map is generated. The pupil map may be generated by convolving a 2D fast Fourier transform (FFT) for the mask pattern around a pupil. For example, the mask pattern may be normalized, and a pupil having a 100% of pupil fill ratio (PFR) may be used. The PFR may refer to a ratio of an area of a pupil surface on which light is incident to a pupil surface. The pupil map may appear in the form of a 2D FFT image, as shown in FIG. 3. The pupil map is described in more detail below with reference to FIG. 3.

The pupil map may be used to define a first region described below. In addition, the pupil map may be used to generate a top-hat. For example, the top-hat may be generated to exclude EUV point sources that are unnecessary in the EUV illumination mode. By excluding EUV point sources unnecessary in the EUV illumination mode through the top-hat operation before calculating aerial images for all EUV point sources, an amount of time needed to calculate aerial images for EUV point sources may be significantly reduced.

Here, the EUV point source is the smallest unit that may be individually turned on/off and may be generated by segmenting the EUV illumination mode. Each of the EUV point sources may have incoherence. In other words, light originating from EUV point sources at different positions may have the property of not interfering with each other. Thus, each of the EUV point sources may be treated independently of each other. In addition, the entire EUV illumination mode may be configured by summing up the EUV point sources. For example, the entire EUV illumination mode may be configured by adding up all EUV point sources. The configuration of the EUV illumination mode by segmenting the EUV point sources or summing the EUV point sources is described in more detail using the concept of EUV mapping below.

According to an embodiment, an aerial image for a point source may be calculated through optical simulation. The aerial image may refer to, for example, a point source displayed as an intensity profile on the x-axis and y-axis, as shown in the graph of FIG. 6B. According to an embodiment, optical simulation refers to a process of precisely calculating the intensity of light from a light source two-dimensionally or one-dimensionally and may be performed through a rigorous simulation tool. In the method of configuring an EUV source according to an embodiment, optical simulation is not limited to a specific software tool and may be performed through any type of software tool as long as the intensity of light may be precisely calculated two-dimensionally or one-dimensionally. Here, by excluding unnecessary EUV point sources through the generation of a top-hat based on a drawing method, the time to calculate aerial images for EUV point sources may be significantly reduced.

In operation S130, the method may include configuring EUV illumination mode based on the pupil map. For example, after calculating the pupil map, an EUV illumination mode may be configured by selecting mirrors in at least a portion of the first region of the pupil map in which a condition is satisfied. The condition may be a one or more predetermine conditions. Here, the mirrors may refer to pupil facet mirrors (PFM). In the first region of the pupil map, the maximum overlap region in which the largest number of beams overlap by mirrors in the pupil map may be defined as the corresponding maximum overlap region, which is equal to or greater than an area in which illumination efficiency 1 is achieved. The area in which illumination efficiency is 1 may be referred to as an ‘area of illumination efficiency 1’. In an example case in which the maximum overlap region is smaller than the area of illumination efficiency 1, the first region of the pupil map may include up to the next maximum overlap region until the maximum overlap region is equal to or larger than the area of illumination efficiency 1. For example, the first region of the pupil map may include a region in which the next largest number of beams overlap, and has an area equal to or larger than the area of illumination efficiency 1. According to an embodiment, illumination efficiency 1 may refer to a state in which all point sources are used. The first region of the pupil map and illumination efficiency 1 are described in more detail below reference to FIGS. 2A, 2B and 3.

According to an embodiment, in the method of configuring an EUV source, the operation S130 of configuring the EUV illumination mode may include applying perturbation of a pole balance. Here, the perturbation of the pole balance may refer to a process of changing the combination of selected mirrors, without significantly changing the entire EUV illumination mode. In addition, the perturbation of the pole balance may refer to searching for combinations of mirrors that break pole balance. Accordingly, in the method of configuring an EUV source according to an embodiment, the pole balance may be broken through the perturbation of the pole balance, and asymmetry of the pupil map may also be introduced.

According to an embodiment, in the method of configuring an EUV source, the perturbation of the pole balance in the operation S130 of configuring the EUV illumination mode may be applied to some processes within a general source and mask optimization (SMO) tool or optimization of the EUV illumination mode independently, regardless of the SMO tool. For reference, to briefly describe the SMO tool, the SMO tool may largely include a pre-processing operation, an illumination mode optimization operation, and a post-processing operation. In the case of the preprocessing operation, processing related to a focus depth may be mainly performed. In the case of the illumination mode optimization operation, a series of processes to optimize the illumination mode may be performed. In the case of the post-processing operation, dose optimization, mask optimization, etc. may be performed.

According to an embodiment, the perturbation of the pole balance may be applied to the illumination mode optimization operation. For example, the perturbation of the pole balance may be applied to at least one of a freeform source (FFS) and mask optimization process, an EUV source rendering process, and an individual mirror and mask optimization process included in the illumination mode optimization operation. The FFS and mask optimization process may correspond to a process of configuring a mask optical proximity correction (OPC) and a shape of the corresponding rough illumination mode in response to a target pattern. The EUV source rendering process may correspond to a process of changing intensity information of the illumination mode into information on mirrors. In other words, the EUV source rendering process may correspond to a process of determining a combination of mirrors selected in response to the pupil map described above. The individual mirror and mask optimization process may correspond to a process of further optimizing the illumination mode by changing the positions of selected mirrors. According to an embodiment, the application of the perturbation of the pole balance may be automated with the SMO tool. For example, the perturbation of the pole balance may be automated by parameterizing the pupil map and determining an arrangement ratio of the mirrors selected for each pole position through the parameter in at least one of the three processes described above.

In an example case in which the perturbation of the pole balance is applied to the optimization of the EUV illumination mode independently of the SMO tool, mirrors may be selected within at least a portion of the first region of the pupil map and the arrangement ratio of the selected mirrors is reflected variously for each pole position. For example, through optical simulation, mirrors may be selected for each pole position so that an aspect ratio of a CD of an after-development inspection (ADI) is targeted in each illumination mode. In addition, mirrors may be selected by pole position to improve optical performance, e.g., reduce LCDU, and/or increase NILS.

According to an embodiment, applying the perturbation of the pole balance to the optimization of the EUV illumination mode independently of the SMO tool may also be automated. For example, it may be automated by parameterizing the pupil map and determining the arrangement ratio of the mirrors selected for each pole position through the parameter. In addition, it may be automated by arbitrarily dividing the regions of the pupil map regardless of the poles of the pupil map and determining the arrangement ratio of the selected mirrors for each region.

The method of configuring an EUV source according to an embodiment may include an operation of configuring an EUV illumination mode by selecting mirrors in at least a portion of the first region of the pupil map in which a certain condition is satisfied, and further, in the operation of configuring the EUV illumination mode, the optical performance of the EUV illumination mode may be improved before an exposure process by applying the perturbation of the pole balance. For example, the method of configuring an EUV source according to an embodiment may minimize LCDU, increase NILS, and reduce dose through the perturbation of the pole balance. Here, as described above, in the first region of the pupil map, the maximum overlap region in which the largest number of beams overlap by mirrors in the pupil map is defined as the corresponding maximum overlap region which is equal to or greater than an area of illumination efficiency 1, and in an example case in which the maximum overlap region is smaller than the area of illumination efficiency 1, the first region of the pupil map may include up to the next maximum overlap region until the maximum overlap region is equal to or larger than the area of illumination efficiency 1. For example, the first region of the pupil map may include a region in which the next largest number of beams overlap, and has an area equal to or larger than the area of illumination efficiency 1.

Regarding EUV mapping, the EUV light from the EUV source that is focused within the first optical system before the EUV light is focused on the EUV mask is referred to as intermediate focusing light. According to an embodiment, the first optical system may cause intermediate focusing light to be incident on the EUV mask. The intermediate focusing light transmitted through the first optical system may correspond to an field facet mirror (FFM) and the PFM. For example, the FFM may represent a form of an electromagnetic field of EUV light transmitted through the first optical system, and the PFM may represent a form of an electromagnetic field of EUV light on a pupil surface of the EUV mask. In general, in an EUV facility, there may be limiting conditions in selecting an optical path from M (a positive integer) FFMs to N (an integer greater than M) PFMs. According to an embodiment, such limiting conditions in selecting the optical path from the FFMs to the PFMs may correspond to the EUV mapping.

Meanwhile, there may be countless combinations of PFMs by EUV mapping. According to an embodiment, EUV mapping may be performed such that one FFM selects one of a limited number of PFMs. Accordingly, a combination of PFMs may be configured in a two-dimensional matrix form. That is, one of the limited number of PFMs may be selected to correspond to each of the FFMs.

FIGS. 2A and 2B are conceptual diagrams of an object spectrum map in the method of configuring an EUV source of FIG. 1. FIG. 2A shows an object spectrum map with a crosspole illumination mode and FIG. 2B shows an object spectrum map with a Y-dipole illumination mode. The description already provided above with reference to FIG. 1 is briefly given or omitted.

Referring to FIGS. 2A and 2B, the object spectrum maps may be generated to correspond to the layout of a mask pattern. The object spectrum maps may be generated in an automated manner to some extent. In other words, in an example case in which the layout of the mask pattern is input, the shape of the layout may be parameterized, and the object spectrum maps may be automatically generated through a map generation tool based on the parameter. In FIGS. 2A and 2B, relatively large light gray dots (D1-D5) within a circle and dark gray dots (OD) outside the circle may correspond to poles of the object spectrum map. In detail, the dot D1 in the exact center of the circle may be a pole caused by 0-th order diffraction light, and four outermost dots (D2-D5) within the circle in the diagonal direction and the dark gray dots (OD) outside the circle may be poles caused by first order diffraction light. According to an embodiment, small circles within the circle may correspond to selected mirrors Mr corresponding to EUV point sources. According to an embodiment, in FIGS. 2A and 2B, the intensity of the pole due to the 0-th order diffraction light in the center and the intensities of the poles due to the first order diffraction light outside the circle in the x and y directions are shown together. When comparing FIGS. 2A and 2B, it can be seen that the intensities of the other poles are similar, but the intensities of the two poles outside the circle in the y direction appear to be relatively large in FIG. 2B.

In the object spectrum map of FIG. 2A, mirrors may be densely arranged in the upper, lower, left, and right portions of the circle. Accordingly, the EUV illumination mode shown together in FIG. 2A may correspond to a crosspole type illumination mode. For reference, the crosspole may also be referred to as a 4-pole pole according to an embodiment. In contrast, in the object spectrum map of FIG. 2B, mirrors may be densely placed in the upper and lower portions of the circle. Accordingly, the EUV illumination mode shown in FIG. 2B may correspond to a Y-dipole type illumination mode.

According to an embodiment, the upper left patterns (MP) of FIGS. 2A and 2B may correspond to the layouts of mask patterns corresponding to a crosspole type illumination mode and a Y-dipole type illumination mode, respectively. The layout of the mask pattern in FIG. 2B may have a major axis in the x direction relatively larger than the layout of the mask pattern in FIG. 2A. Therefore, for a target pattern with a large major axis in the x-direction, the EUV illumination mode may be optimized by configuring a Y-dipole type illumination mode instead of a crosspole dipole type illumination mode.

FIG. 3 is a conceptual diagram of a pupil map in relation to the method of configuring an EUV source of FIG. 1. The description already provided above with reference to FIGS. 1 to 2B is briefly given or omitted.

Referring to FIG. 3, the pupil map may be generated by convolving a 2D FFT for the mask pattern with a pupil, as described above. Because the pupil map corresponds to overlapped diffraction light, the pupil map may also be referred to as an overlapped diffraction order map. In addition, the pupil map corresponds to interference in an object spectrum, so the pupil map is also referred to as an object spectrum interference map.

The pupil map may be used to define the first region described below. In addition, the pupil map may be used to generate a top-hat. For example, the top-hat may be generated to exclude EUV point sources that are unnecessary in the EUV illumination mode. Before calculating aerial images for all EUV point sources, EUV point sources unnecessary in the EUV illumination mode may be excluded through the top-hat operation, thereby significantly reducing the time to calculate aerial images for EUV point sources.

Hereinafter, the first region of the pupil map is described with reference to FIGS. 2A and 2B together. In the pupil map of FIG. 3, the light gray portion in the central portion corresponds to a pole based on 5-beam imaging, and \hat{1}, \hat{2}, \hat{3}, and \hat{4} on the top, bottom, left, and right may correspond to poles based on 4-beam imaging. Here, 5-beam imaging may refer to imaging using 5 spectra within the pupil, and 4-beam imaging may refer to imaging using 4 spectra.

In detail, the central pole is imaging using 0-th order diffraction light disposed in the center and 4 pieces of first order diffraction light arranged in two diagonal directions. According to an embodiment, \hat{1}, \hat{2}, \hat{3}, and \hat{4} are each imaging using the central 0-th order diffraction light and the three pieces of first order diffraction light therearound. For example, the pole of \hat{1} is imaging using the central 0-th order diffraction light and first order diffraction light in the north, northwest, and northeast.

In the first region of the pupil map, the maximum overlap region in which the largest number of beams overlap by mirrors in the pupil map is defined as the corresponding maximum overlap region which is equal to or greater than an area of illumination efficiency 1. In an example case in which the maximum overlap region is smaller than the area of illumination efficiency 1, the first region of the pupil map may include up to the next maximum overlap region until the maximum overlap region is equal to or larger than the area of illumination efficiency 1. For example, the first region of the pupil map may include a region in which the next largest number of beams overlap, and has an area equal to or larger than the area of illumination efficiency 1. Here, as described above, illumination efficiency 1 may refer to a state in which all point sources are used, that is, a state in which all mirrors corresponding to all point sources are selected. In addition, the area of illumination efficiency 1 may correspond to the area occupied by the selected mirrors, i.e., the small circles, in FIG. 2A, for example. In FIG. 3, the central 5-beam imaging pole region may be smaller than the area of illumination efficiency 1, and therefore has to include the 4-beam imaging regions, i.e., the regions of \hat{1}, \hat{2}, \hat{3}, \hat{4} poles, to be larger than the area of illumination efficiency 1. Therefore, in the pupil map of FIG. 3, the first region of the pupil map may correspond to the regions occupied by the central 5-beam imaging pole region and all 4-beam imaging poles of \hat{1}, \hat{2}, \hat{3}, and \hat{4}.

In an example case in which the EUV illumination mode is implemented by uniformly selecting mirrors throughout the first region based on the first region of the pupil-map, pole balance in a crosspole form and symmetry of the pupil-map may be maintained. However, the EUV illumination mode that maintains pole balance in a crosspole form and symmetry of the pupil-map may have poor optical performance.

Accordingly, in the method of configuring an EUV source according to an embodiment, in the operation of configuring the EUV illumination mode, not only is the EUV illumination mode implemented in the crosspole form by selecting mirrors uniformly across the poles \hat{1}, \hat{2}, \hat{3}, and \hat{4}, but also the EUV illumination mode is implemented in a dipole-like form by selecting mirrors of the region of the poles of \hat{1} and \hat{2} or selecting mirrors of the region of the poles of \hat{3} and \hat{4}, thereby improving optical performance. For reference, implementing the EUV illumination mode by selecting only mirrors in a portion of the first region may correspond to perturbation of the pole balance. Such perturbation of the pole balance may cause the pole balance to be broken and also introduce asymmetry into the pupil-map.

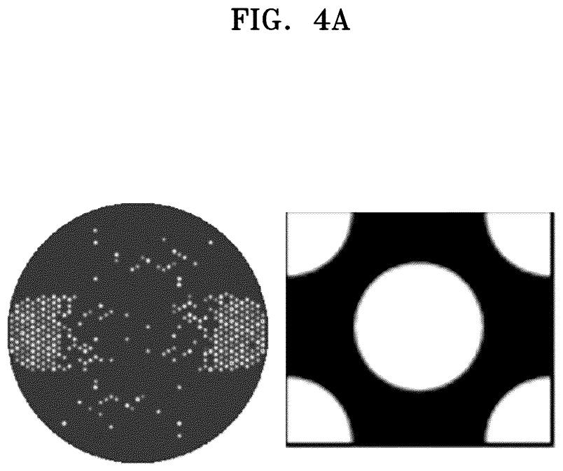

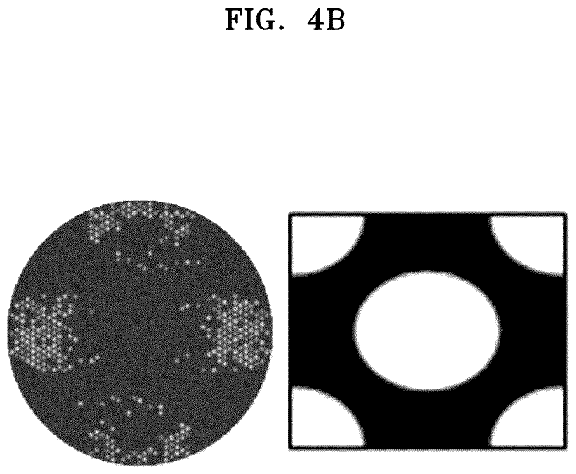

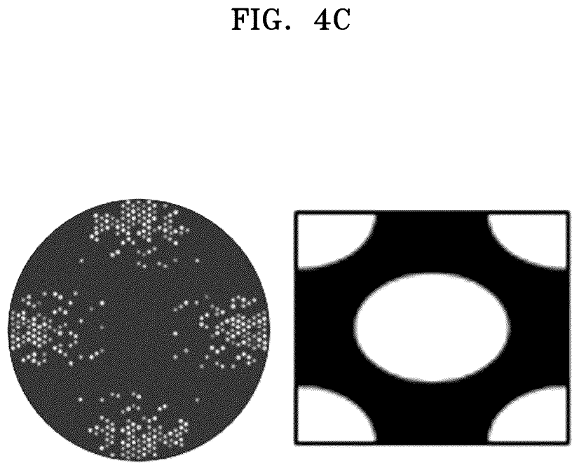

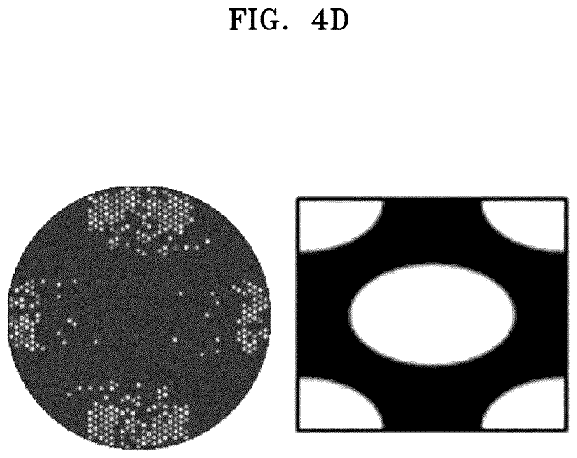

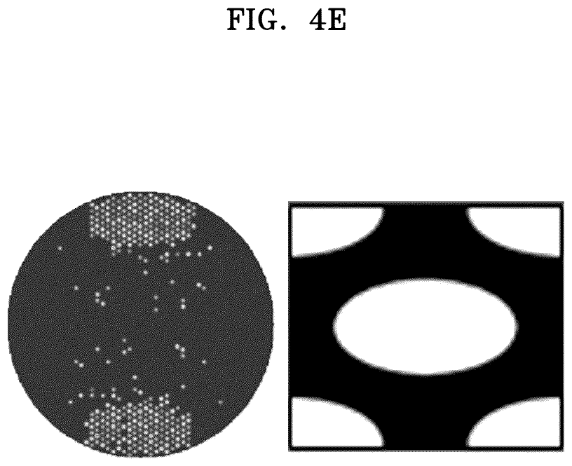

FIGS. 4A to 4E are conceptual diagrams of various EUV illumination modes configured by applying perturbation of pole balance in the method of configuring an EUV source of FIG. 1, and layouts of mask patterns corresponding to the various EUV illumination modes. The description already provided above with reference to FIGS. 1 to 3 is briefly given or omitted.

Referring to FIG. 4A, an EUV illumination mode configured by selecting most of the mirrors within the regions of poles \hat{3} and \hat{4} in the pupil map of FIG. 3 is illustrated. Accordingly, the EUV illumination mode of FIG. 2A may correspond to an X-dipole or an X-dipole-like illumination mode. As can be seen from the layout of the mask pattern on the right, the X-dipole illumination mode corresponds to a mask pattern that is almost circular. Referring to FIG. 4B, an EUV illumination mode is configured by selecting mirrors within the region of poles \hat{1}, \hat{2}, \hat{3}, and \hat{4} in the pupil map of FIG. 3, that is, by selecting a relatively large number of mirrors in the region of poles \hat{3} and \hat{4}, and selecting a smaller number of mirrors within the region of poles \hat{1} and \hat{2}. The EUV illumination mode of FIG. 4B may correspond to a crosspole illumination mode in which x-axis poles are strengthened (hereinafter, referred to as ‘X-axis-enhanced crosspole illumination mode’). As can be seen from the layout of the mask pattern on the right, the X-axis-enhanced crosspole illumination mode may correspond to an elliptical mask pattern. Referring to FIG. 4C, an EUV illumination mode is configured by selecting mirrors within the region of poles \hat{1}, \hat{2}, \hat{3}, and \hat{4} in the pupil map of FIG. 3, that is, by selecting the mirrors uniformly throughout the region of the poles \hat{1}, \hat{2}, \hat{3}, and \hat{4}. The EUV illumination mode of FIG. 4C may correspond to a pole-balanced crosspole illumination mode. As can be seen from the layout of the mask pattern on the right, the pole-balanced crosspole illumination mode may also correspond to the elliptical mask pattern. Referring to FIG. 4D, an EUV illumination system is configured by selecting mirrors in the region of poles \hat{1}, \hat{2}, \hat{3}, and \hat{4} in the pupil map of FIG. 3, that is, by selecting a relatively large number of mirrors in the region of poles \hat{1} and \hat{2} and selecting a small number of mirrors in the region of poles \hat{3} and \hat{4}. The EUV illumination mode of FIG. 4D may correspond to a crosspole illumination mode in which y-axis poles are enhanced (hereinafter, referred to as ‘Y-axis-enhanced crosspole illumination mode’). As can be seen from the layout of the mask pattern on the right, the Y-axis-enhanced crosspole illumination mode may correspond to an elliptical mask pattern. Referring to FIG. 4E, an EUV illumination mode is configured by selecting most of the mirrors within the region of the poles \hat{1} and \hat{2} in the pupil map of FIG. 3. Accordingly, the EUV illumination mode of FIG. 4E may correspond to a Y-dipole or Y-dipole-like illumination mode. As can be seen from the layout of the mask pattern on the right, the Y-dipole illumination mode may correspond to an elliptical mask pattern. Based on the NILS value, it may be predicted that the Y-dipole illumination mode of FIG. 4E corresponds to the optimal EUV illumination mode. For example, in the case of the Y-dipole illumination mode, NILS may increase by 7% or more compared to a crosspole illumination mode.

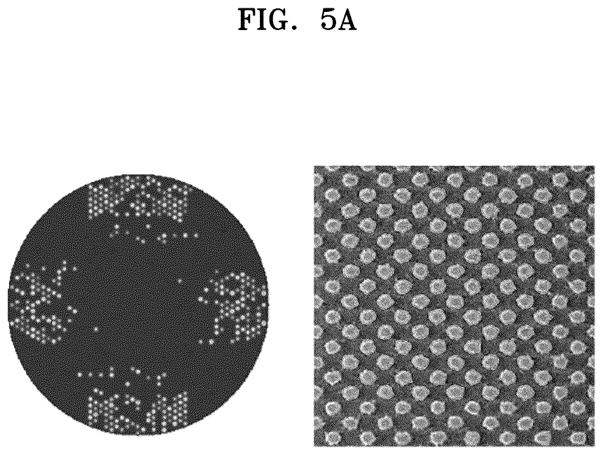

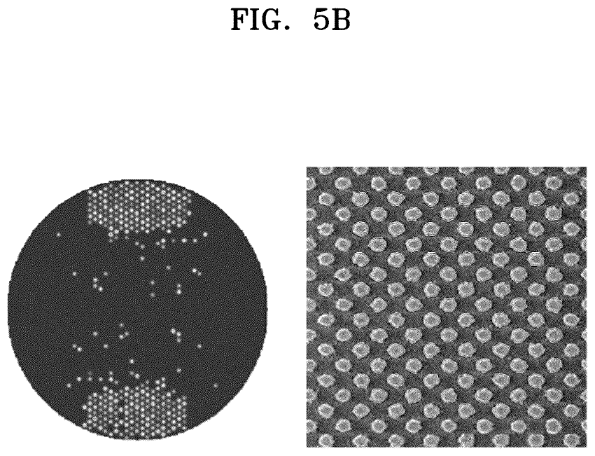

FIG. 5A is a conceptual diagram of a crosspole illumination mode and a scanning electron microscope (SEM) image of a target pattern according to a comparative example and FIG. 5B is a conceptual diagram of a Y-dipole illumination mode and a scanning electron microscope (SEM) image of a target pattern based on a method of configuring an EUV source according to an embodiment.

Referring to FIGS. 5A and 5B, when comparing the crosspole illumination mode of the comparative example of FIG. 5A and the Y-dipole illumination mode according to an embodiment of FIG. 5B, an LCDU may be improved by 9%, and an effective dose may be improved by 25%. In addition, the SEM images on the right show that the uniformity of the pattern is improved.

FIGS. 6A to 6C are conceptual diagrams illustrating the concepts of mask pattern layout, aerial image, and NILS in relation to the method of configuring an EUV source of FIG. 1.

FIG. 6A shows cutlines of the major axis and minor axis defined on the layout of the mask pattern to calculate an aerial image. In FIG. 6A, the dashed line square on the layout of the mask pattern is a simulation box, the solid line of the major axis, among the solid lines in the cross-shape inside the square, corresponds to an x-axis cutline, and the solid line of the minor axis corresponds to the y-axis cutline. FIG. 6B shows the intensity on the cutline of the x-axis (graph G1) and y-axis (graph G2) by one EUV point source. In the two graphs G1 and G2 in FIG. 6B, the horizontal axes are positions on the x-axis and y-axis, and the unit is an arbitrary unit, and the vertical axes are intensity, and the unit is also an arbitrary unit. In this manner, an aerial image may be calculated for each point source.

In general, target CD may be calculated through CD targeting. CD targeting may refer to setting the level of threshold intensity TH for the aerial image so that the pattern of the required CD value may be patterned. According to an embodiment, in CD targeting, the CD of the aerial image has an offset from the actual patterned ADI CD, but the offset value is constant in a given CD range, and thus, the CD value may be targeted by considering this. In FIG. 6C, the target CD calculated through CD targeting on the x-axis is indicated by double arrows. That is, the target CD may be calculated by setting the threshold intensity TH on the x-axis.

NILS may be defined as CDx*{dln(I)/dx}, or (CDx/I)*(dI/dx) on the x-axis. That is, NILS may be defined by a CD value CDx, an intensity value I of the aerial image at a point in which the CD value is defined, and a differential value (dI/dx) of the intensity at a point in which the CD value is defined. NILS may be defined by the same concept on the y-axis. In FIG. 6C, the differential value of the intensity, that is, the slope of the intensity, is shown as the dashed line at the point in which the CD value is defined. As described above, NILS is an optical performance showing characteristics that the CD value changes less over a change in process, such as dose and focus, as the value of NILS increases. Therefore, as NILS increases, the performance of the EUV illumination mode or EUV source may be determined to be more optimized.

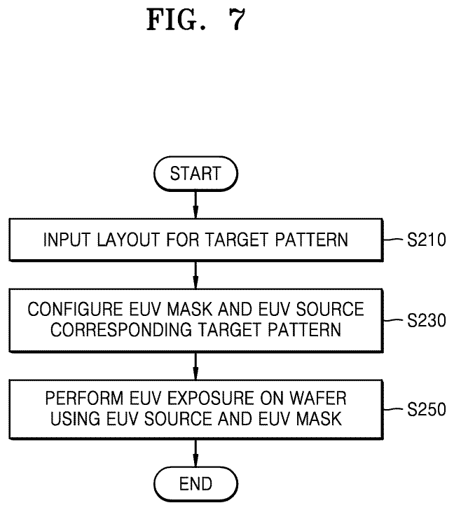

FIG. 7 is a flowchart schematically illustrating an EUV exposure method using an EUV source (hereinafter, referred to as an ‘EUV exposure method’) according to an embodiment. The description already provided above with reference to FIGS. 1 to 6C is briefly given or omitted.

Referring to FIG. 7, in operation S210, the EUV exposure method according to an embodiment may include receiving a layout for a target pattern. Here, the target pattern may refer to a pattern to be formed on a silicon (Si) substrate, such as a wafer. For example, a pattern on a mask may be transferred to the substrate through an exposure process to form a target pattern on the substrate. According to an embodiment, the pattern on the mask is usually scaled down and projected onto the wafer, the pattern on the mask may have a larger size than the target pattern on the substrate.

In operation S230, the EUV exposure method may include configuring the EUV mask and the EUV source based on the target pattern. For example, after the layout of the target pattern is received, the EUV mask and the EUV source may be configured corresponding to the target pattern. The configuration of the EUV mask may include an OPC process and an EUV mask manufacturing process. According to an embodiment, in the configuration of the EUV mask, the OPC process may be performed in combination with the configuration of the EUV source.

According to an embodiment, the configuration of the EUV source may include the method of configuring an EUV source in FIG. 1. Therefore, an optimal EUV source may be implemented through various operations described in the description portion of the method of configuring an EUV source in FIG. 1. According to an embodiment, in the EUV exposure method, the configuration of the EUV source may include configuring the entire EUV optical system.

After the EUV mask and the EUV source are configured, EUV exposure is performed on the wafer using the EUV source and the EUV mask (S250). EUV exposure may refer to projecting EUV light onto an EUV photoresist (PR) layer on a wafer using an EUV source and an EUV mask. According to some embodiments, EUV exposure may include a development process for the PR layer. A PR pattern may be formed through a development process for the PR layer.

The EUV exposure method according to an t embodiment includes the method of configuring an EUV source of FIG. 1 in the operation (S230) of configuring the EUV mask and the EUV source, thereby implementing an EUV source with optimized optical performance, and further, optimal EUV exposure may be performed based on the optimized EUV source. Accordingly, a PR pattern that optimally meets the required patterning performance index may be formed on the wafer.

While the disclosure has been particularly shown and described with reference to embodiments thereof, it will be understood that various changes in form and details may be made therein without departing from the spirit and scope of the following claims.

What is claimed is:

1. A method of configuring an extreme ultraviolet (EUV) source, the method comprising:
generating an object spectrum map for a layout of a mask pattern;
generating a pupil map corresponding to the object spectrum map; and
configuring an EUV illumination mode by:
selecting a plurality of mirrors in a first region of the pupil map based on a first condition being satisfied, and
applying perturbation of a pole balance to the plurality of mirrors.

2. The method of claim 1, wherein,
in the first region, a maximum overlap region in which a largest number of beams overlap by the plurality of mirrors in the pupil map is defined as a corresponding maximum overlap region which is equal to or greater than an area of illumination efficiency 1, the illumination efficiency 1 referring to a state in which all field facet mirrors corresponding to EUV point sources are selected, and
based on the maximum overlap region being smaller than the area of illumination efficiency 1, the first region comprises a next maximum overlap region in which a next largest number of beams overlap, and which has an area equal to or larger than the area of illumination efficiency 1.

3. The method of claim 2, wherein the configuring the EUV illumination mode comprises arranging the plurality of mirrors in a manner in which the pole balance is broken.

4. The method of claim 2, wherein the configuring the EUV illumination mode comprises arranging the mirrors to form a dipole-like illumination mode.

5. The method of claim 2, further comprises:
applying a mask, using a tool for optimizing the EUV source, to search for combinations of the plurality of mirrors in which the pole balance is broken.

6. The method of claim 5, wherein
the combination of the plurality of mirrors is searched for in at least one of a freeform source (FFS) and mask optimization process, an EUV source rendering process, or an individual mirror and mask optimization process included in the tool, and
in the combinations of the plurality of mirrors, an arrangement ratio of the plurality of mirrors selected for each pole position is determined through a parameter.

7. The method of claim 2, further comprises: searching for a combination of the plurality of mirrors in which the pole balance is broken,
wherein, in the combination of the plurality of mirrors, an arrangement ratio of the plurality of mirrors selected for each pole position is determined through a parameter.

8. The method of claim 2, wherein,
based on the pupil map being in a shape of a circle, 0-th order diffraction light is located at a center of the circle and pieces of first order diffraction light are located inside or outside the circle,
the first region is defined by the 0-th order diffraction light and the pieces of first order diffraction light within the circle, and
in the configuring of the EUV illumination mode, the plurality of mirrors are selected to reflect pole ratios in the first region.

9. The method of claim 2, wherein the plurality of mirrors are selected so that an aspect ratio (or long/short ratio) of a critical dimension (CD) of after-development inspection (ADI) corresponding to the mask pattern is targeted.

10. The method of claim 2, wherein the plurality of mirrors are selected to increase normalized image log slope (NILS).

11. A method of configuring an extreme ultraviolet (EUV) source, the method comprising:
generating an object spectrum map for a layout of a mask pattern;
generating a pupil map corresponding to the object spectrum map;
based on a maximum overlap region in which a largest number of beams overlap in the pupil map being equal to or greater than an area of illumination efficiency 1, configuring a EUV illumination mode to a first mode in which the maximum overlap region corresponds to a first region of the pupil map;
based on the maximum overlap region being smaller than the area of illumination efficiency 1, and based on a sum of the maximum overlap region and a next maximum overlap region being equal to or greater than the area of illumination efficiency 1, configuring the EUV illumination mode to a second mode in which the maximum overlap region and the next maximum overlap region correspond to the first region of the pupil map;
selecting a plurality of mirrors in the first region; and
applying perturbation of a pole balance to introduce asymmetry of the pupil map.

12. The method of claim 11, wherein the configuring the EUV illumination mode comprises arranging the plurality of mirrors to form a dipole-like illumination mode.

13. The method of claim 11, further comprises:
applying a mask to search for combinations of the plurality of mirrors in which the pole balance is broken,
wherein the mask is applied using a tool that optimizes an EUV mask or independent of the tool, and
wherein, in the combinations of the plurality of mirrors, an arrangement ratio of the plurality of mirrors selected for each pole position is determined through a parameter.

14. The method of claim 11, wherein,
based on the pupil map being in a shape of a circle, 0-th order diffraction light is located at a center of the circle and pieces of first order diffraction light are located inside or outside the circle,
the first region is defined by the 0-th order diffraction light and the pieces of first order diffraction light within the circle, and
in the configuring of the EUV illumination mode, the plurality of mirrors are selected to reflect various pole ratios in the first region.

15. The method of claim 11, wherein the plurality of mirrors are selected so that an aspect ratio of a critical dimension (CD) of after-development inspection (ADI) corresponding to the mask pattern is targeted and normalized image log slope (NILS) increases.

16. An extreme ultraviolet (EUV) exposure method comprising:
obtaining a target pattern;
configuring an EUV mask and an EUV source corresponding to the target pattern; and
performing EUV exposure on a wafer using the EUV source and the EUV mask, wherein the configuring of the EUV source comprises:
generating an object spectrum map for a layout of a mask pattern on the EUV mask;
generating a pupil map corresponding to the object spectrum map; based on a maximum overlap region in which a largest number of beams overlap in the pupil map being equal to or greater than an area of illumination efficiency 1, configuring a EUV illumination mode to a first mode in which the maximum overlap region corresponds to a first region of the pupil map;
based on the maximum overlap region being smaller than the area of illumination efficiency 1, and based on a sum of the maximum overlap region and a next maximum overlap region being equal to or greater than the area of illumination efficiency 1, configuring the EUV illumination mode to a second mode in which the maximum overlap region and the next maximum overlap region correspond to the first region of the pupil map;
selecting a plurality of mirrors in the first region; and
applying perturbation of a pole balance to introduce asymmetry of the pupil map.

17. The method of claim 16, wherein the configuring the EUV illumination mode comprises arranging the plurality of mirrors to form a dipole-like illumination mode.

18. The method of claim 16, further comprises:
applying a mask to search for combinations of the plurality of mirrors in which the pole balance is broken,
wherein the mask is applied using a tool that optimizes an EUV mask or independent of the tool, and
wherein, in the combinations of the plurality of mirrors, an arrangement ratio of the plurality of mirrors selected for each pole position is determined through a parameter.

19. The method of claim 16, wherein,
based on the pupil map being in a shape of a circle, 0-th order diffraction light is located at a center of the circle and pieces of first order diffraction light are located inside or outside the circle,
the first region is defined by the 0-th order diffraction light and the pieces of first order diffraction light within the circle, and
in the configuring of the EUV illumination mode, the plurality of mirrors are selected to reflect various pole ratios in the first region.

20. The method of claim 16, wherein the plurality of mirrors are selected so that an aspect ratio of a critical dimension (CD) of after-development inspection (ADI) corresponding to the mask pattern is targeted and normalized image log slope (NILS) increases.
